(19) United States
(12) Patent Application Publication
(10) Pub. No.: US 2025/0333844 A1
(43) Pub. Date: Oct. 30, 2025

(54) METHOD AND ASSEMBLY FOR PROVIDING PROCESS GAS TO A CVD REACTOR

(71) Applicant: AIXTRON SE, Herzogenrath (DE)

(72) Inventor: Peter Sebald LAUFFER, Aachen (DE)

(21) Appl. No.: 18/576,689

(22) PCT Filed: Jul. 1, 2022
(86) PCT No.: PCT/EP2022/068288

§ 371 Date: Jan. 4, 2024

(30) Foreign Application Priority Data
Jul. 6, 2021 (DE) 10 2021 117 457.0

(51) Int. Cl. C23C 16/52; C23C 16/455

(52) U.S. Cl. CPC C23C 16/52; C23C 16/45561

(57) ABSTRACT

An assembly for providing a process gas for use in a CVD reactor includes an inlet mass flow controller for providing a carrier gas flow which flows into an evaporation device. The carrier gas flow conveys the vapor of a starting material from a container of the evaporation device through a process gas feed line to the CVD reactor. The total pressure in the process gas feed line can be held at a predefined value by a pressure controller. In order to hold the mass flow of the starting material, which mass flow is to be fed into the CVD reactor, sufficiently constant over time, the gas stream flowing through the process gas feed line is controlled by a mass flow controller, and the concentration of the starting material in the process gas feed line at a predefined total pressure is measured.

### RELATED APPLICATIONS

This application is a National Stage under 35 USC 371 of and claims priority to International Application No. PCT/EP2022/068288, filed 1 Jul. 2022, which claims the priority benefit of DE Application No. 10 2021 117 457.0, filed 6 Jul. 2021.

### FIELD OF THE INVENTION

The invention relates to an assembly for providing a process gas for use in a chemical vapor deposition (CVD) reactor, in particular in a metal organic chemical vapor deposition (MOCVD) reactor. A carrier gas, for example hydrogen or nitrogen, is provided with an inlet mass flow controller or an assembly of a plurality of inlet mass flow controllers. The carrier gas may optionally be connected directly to a process gas feed line, which opens into a gas inlet element of a CVD reactor, or to an inlet of a source in the form of an evaporation apparatus. In the latter case, an outlet of the evaporation apparatus is connected to the process gas feed line, so that a vapor of a liquid or solid starting material stored in a container of the evaporation apparatus is conveyed with the carrier gas through the process gas feed line to the CVD reactor. The vapor pressure of the starting material in the container may be adjusted by a temperature control apparatus with which the container may be heated or cooled. When the assembly is used in an MOCVD reactor, the container contains an organometallic starting material. Additional gas sources are provided, with which other, in particular gas-phase, starting materials are fed directly into the gas inlet element of the CVD reactor, so that gases of two different chemical elements, for example elements of main group V and III are fed into the process chamber of the CVD, so that a semiconductor layer of elements of main group III and V is deposited on a substrate arranged in the process chamber, which substrate is heated to a process temperature.

In addition, sources may also be provided in a central gas supply, with which a mass flow of a gas stored in a container, for example propane or the like, is provided, which is transported to one or more CVD reactors with a carrier gas. The concentration of the reactive gas in the carrier gas may vary. Instead of a gas stored in a container, however, a source may also be used in which a solid or liquid starting material is vaporized and the vapor is conveyed to one or more CVD reactors by a carrier gas in the manner described above. Here too, the concentration of the reactive gas in the gas stream may vary over time, particularly when containers have been changed.

### BACKGROUND

EP 1 870 490 A2 describes an evaporation device with a feed line through which a carrier gas regulated by a mass flow controller is fed into an inlet of an evaporator. The outlet of the evaporator opens into a process gas feed line, into which another carrier gas feed line opens. A balancing gas flows through this carrier gas feed line, with which the process gas flow coming from the evaporator is diluted. A pressure regulator is provided, with which the mass flow of the compensation gas is adjusted in such a way that the total pressure in the container of the source and in the process gas feed line is kept at a constant value.

It is also known from the prior art to arrange a measuring apparatus in the process gas feed line, with which to measure the concentration and/or the partial pressure of the vapor of the starting material in the process gas feed line. For this purpose, measuring apparatuses are used in particular which generate a sound signal, in particular an ultrasonic signal, and measure the sound propagation time or the speed of sound within the process gas. Since the speed of sound depends on the concentration of the starting material in the carrier gas, the concentration and/or the partial pressure may be determined from the measured values obtained in this way. However, the measured value of this measuring assembly also depends on the total pressure in the process gas feed line and/or a measuring chamber of the measuring apparatus.

It is also desirable to feed a predetermined flow of process gas into a gas inlet element of a CVD reactor and, in particular, to feed various predetermined flows of process gas into a CVD reactor through gas inlet openings arranged at different points. It is also desirable to provide a central gas supply with which process gases may be provided with a concentration that is stable over time.

### SUMMARY OF THE INVENTION

The object of the invention is to feed a precisely adjustable mass flow of a starting material to a CVD reactor.

The invention is also based on the object of specifying measures with which the total pressure is kept at a constant value both in the container of the source and in the process gas feed line.

The invention is further based on the object of describing a CVD reactor and a method for providing a process gas.

The object is achieved with the invention specified in the claims. The subordinate claims are not only advantageous further developments of the independent claims but also solutions to the task in their own right.

The invention relates firstly and essentially to an assembly for providing a process gas for use in a known CVD reactor. The assembly according to the invention may be part of a gas supply system for a CVD reactor. The assembly has a feed line which is or may be connected to a carrier gas source. However, several feed lines may also be provided, which may be connected to different carrier gas sources. Thus, different carrier gases may be used. The assembly has a discharge line, which may be connected in particular as a process gas feed line to a gas inlet element of a CVD reactor. Embodiments of the invention may include a first inlet mass flow controller for providing a first mass flow of a carrier gas, a reactive gas, or a mixture of a carrier gas and a vapor or reactive gas. The inlet of the first inlet mass flow controller may be connected to a carrier gas source. An outlet of the first inlet mass flow controller may be connected to a feed line of an evaporation apparatus. This may be done by means of a switching device. The evaporation apparatus has a container that forms an evaporation volume. A starting material to be evaporated may be stored in the container. It may be a liquid or a solid starting material. The feed line discharges into the container in such a way that the carrier gas flowing in through the feed line flows through the powdered or liquid starting material in order to be saturated with the vapor of the starting material. A discharge line of the evaporation apparatus originating from the evaporation volume is connected to a process gas feed line to the CVD reactor. A mass flow consisting of the carrier gas and a reactive gas, for example the vaporized starting material, flows into and/or through the process gas feed line to the CVD reactor. Additional feed lines may be provided through which other gas-phase starting materials are discharged into the CVD reactor. In particular, it is provided that an organometallic starting material of an element of main group III is vaporized and a gas of an element of main group V is fed to the CVD reactor through a separate feed line.

However, the inlet of the inlet mass flow controller may also be connected to a source of a reactive gas. Whereas in the variant described above only the carrier gas flows through the inlet mass flow controller, in the second variant the reactive gas, or a mixture of the reactive gas and the carrier gas, or a vapor generated in a central evaporation apparatus, flows through the inlet mass flow controller, in particular together with a carrier gas. The gas sources in this variant may be central gas sources that are assigned to a central gas supply and which supplies a plurality of CVD reactors with one or more process gases. The central evaporation apparatus may have the properties described above, wherein the central evaporation apparatus has a larger container for accommodating the starting material to be evaporated, wherein it may be provided that this container is continuously refilled from a storage container.

It may be provided that the source of the process gas is a container in which a gas-phase starting material is stored, wherein the gas-phase starting material may be, for example, a hydride. However, the gas-phase starting material may also be any other reactive gas, that is to say in particular also a carbon-containing gas, a silicon-containing gas or the like. The gas may be stored in the container in its purest form. However, the gas may also be stored in the container together with another gas as a gas mixture. Especially in the latter case, the concentration of the reactive gas in the container may depend on the respective batch.

In the CVD reactor there is a susceptor that can be heated to a process temperature, on which a substrate to be coated is located. Several substrates may also be coated simultaneously in a process chamber of the CVD reactor. For this purpose, the different process gases are fed into the process chamber together with a carrier gas by means of a gas inlet element. According to the invention, it is proposed that an inlet of a pressure regulator is connected to a second or the same carrier gas source to which the first inlet mass flow controller is connected. The pressure regulator may supply a balancing gas that is fed into the process gas feed line in order to keep the total pressure in the process gas feed line at a constant value. With the pressure regulator, the total pressure within the container of the vaporization apparatus may also be kept at a constant value at the same time. According to a further aspect of the invention, it is proposed that at least one further mass flow controller be arranged in the process gas feed line between the outlet of the pressure regulator and the CVD reactor or downstream of the pressure regulator. Since the process gas mass flow flows through this mass flow controller, it is referred to below as the process gas mass flow controller. According to a further aspect of invention, it is proposed that an apparatus for measuring the concentration or the partial pressure of the vapor of the starting material be arranged in the process gas feed line between the outlet of the pressure regulator and the CVD reactor or downstream of the pressure regulator and upstream of the process gas mass flow controller. With the pressure regulator, the total pressure is kept at a constant value in a measuring chamber of this measuring apparatus for measuring the concentration and/or the partial pressure, in which a sound signal is generated by an ultrasonic generator, whose sound propagation time may be measured over a measuring section so that the measured value is not distorted by varying total pressures. The process gas mass flow controller may be arranged between the measuring apparatus and the CVD reactor. The process gas mass flow controller controls the mass flow of the reactive gas entering the CVD reactor. The combination of a process gas mass flow controller with a pressure regulator and an apparatus for measuring the concentration and/or partial pressure also has the advantage that the setpoint of the process gas mass flow controller and/or the inlet mass flow controller may be corrected. The mass flow value supplied by the process gas mass flow controller may depend on the concentration or the partial pressure of the vapor in the process gas feed line. With the measures described above, the performance of a source assembly for a MOCVD reactor may be improved with regard to the incorrectness of an adjustable mass flow of a starting material. According to a further development of one of the aspects described above or several of the aspects of the invention described above, it is possible to divide the process gas flow maintained at a constant total pressure by the pressure sensor or the mass flow determined by the measuring apparatus with regard to its concentration or partial pressure into several partial mass flows. For this purpose, the process gas feed line may split into two or more gas feed lines, in each of which a process gas mass flow controller is arranged. The mass flows of the process gas regulated by the process gas mass flow controllers may be fed into the process chamber of the CVD reactor at different points. For this purpose, the CVD reactor may have a gas inlet element with a plurality of gas inlet openings arranged at various points. In a further development of the invention, a single pressure regulator may be used to generate a plurality of balancing gases, which can be fed into process gas feed lines of different reactor assemblies. The process gas feed lines of the different CVD reactors are kept at the same total pressure in this configuration. For this purpose, the outlet of the pressure regulator is connected to various process gas feed lines via various gas feed lines, wherein the gas feed lines preferably each discharge into the process gas feed line upstream of process gas mass flow controllers and/or upstream of a measuring apparatus for measuring the concentration of the partial pressure.

In the assembly according to the invention for providing a process gas, it may be provided in particular that the total pressure in the process gas feed line is or may be kept at a predetermined value by feeding in a balancing gas flow of a carrier gas with a pressure regulator, wherein the gas stream flowing through the process gas feed line to the CVD reactor is regulated with a mass flow controller arranged in the process gas feed line, downstream of the pressure regulator or the feed point of the balancing gas supplied by the pressure regulator.

With the apparatus according to the invention and the method according to the invention, a process gas mass flow which is generated by a central gas source, or which is generated by a gas source individually assigned to each CVD reactor may be kept at a constant pressure. It is also possible to keep the concentration of the reactive gas within the carrier gas flow at a constant value regardless of the mass flow supplied by the source. It is further possible to maintain the pressure in a plurality of evaporation vessels associated with a single or multiple CVD reactors at a common pressure with only one pressure regulator.

A variant of the invention relates to such a gas supply apparatus or a CVD reactor of such kind, in which a source of a gas-phase starting material, which may be a vaporized liquid, a vaporized solid or a starting material supplied from a gas cylinder, provides a concentration of the starting material in a carrier gas that is variable over time. In order to also provide a temporally constant mass flow of a process gas that has a temporally constant partial pressure of the starting material with a source of such kind, it is proposed that the gas-phase starting material is fed with an inlet mass flow controller into the process gas feed line, into which a gas feed line of a pressure regulator opens, with which the total pressure in the process gas feed line is kept at a constant value by feeding in a balancing gas. The pressure in the measuring apparatus for measuring the concentration of a partial pressure is also kept constant in the pressure regulator. The measuring apparatus delivers a measured value that is supplied to a control apparatus. This control apparatus may supply a setpoint with which the inlet mass flow controller is operated in such a way that the process gas mass flow controller receives a gas mixture with a mixture that remains constant. A process gas mass flow controller may be provided downstream of the measuring apparatus.

It may thus be provided that in a gas flow of a gas-phase starting material or a mixture of a gas-phase starting material and a carrier gas, which is regulated by an inlet mass flow controller and in which the partial pressure of the starting material is subject to fluctuations over time, a dilution gas flow of a carrier gas regulated by a pressure regulator is fed in downstream of the inlet mass flow controller, and these two gas streams are fed into a measuring apparatus for measuring the partial pressure or the concentration of the starting material, wherein the total pressure within the measuring cell of the measuring apparatus is kept constant with a pressure regulator, which also feeds a balancing gas stream into the measuring cell, and the mass flow of the starting material is varied with a control device in such a way that the concentration or the partial pressure of the starting material only varies within narrow limits in the measuring cell. The sum of the mass flow of the starting material and of the dilution gas stream is kept constant by the process gas mass flow controller provided downstream of the measuring point, which causes a change in the dilution gas flow via the pressure regulator.

### BRIEF DESCRIPTION OF THE DRAWINGS

The invention is explained in more detail below with reference to exemplary embodiments. In the drawings:

FIG. 1 shows a schematic diagram of a source assembly for providing a vaporized organometallic starting material,

FIG. 2 shows a schematic representation of FIG. 1, but of a second exemplary embodiment, in which a pressure regulator 8 is connected via a plurality of gas feed lines 12, 12′, 12″ to various process gas feed lines 9, 9′, 9″ of a total of three reactor assemblies,

FIG. 3 is a schematic representation of FIG. 1, in which a process gas feed line 9 is split into two process gas feed lines 9′, 9″, through each of which a process gas flows to different gas inlet openings 15, 15′ of a gas inlet element of a CVD reactor 1 by means of process gas mass flow controllers 13, 13′,

FIG. 4 shows a further exemplary embodiment of the invention, in which a reactive gas is taken from a gas container which contains a concentration of a reactive gas that is dependent on the respective batch,

FIG. 5 shows a further exemplary embodiment in which a central gas source with an evaporation source feeds a number of CVD reactors,

FIG. 6 shows another exemplary embodiment of the invention in which a CVD reactor is fed from a plurality of gas sources, for each of which the same total pressure is maintained in the evaporation vessel,

FIG. 7 shows a further exemplary embodiment in which a vapor of a reactive gas from a central vaporization source 19 is used,

FIG. 8 shows a further exemplary embodiment in which two process gas mass flow controllers 13, 13′ are connected in parallel with one another, and shows a further exemplary embodiment in which FIG. 9 two process gas mass flow controllers 13, 13′ are connected in parallel with one another.

### DETAILED DESCRIPTION

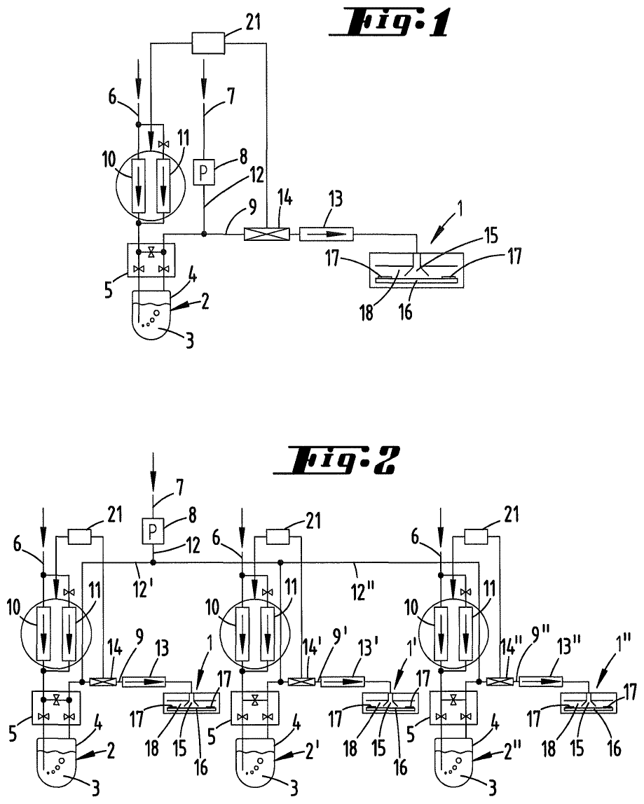

The source assemblies shown in FIGS. 1 to 3 and 5 and 6 each have at least one source for providing a vapor of a solid or liquid starting material 3, which is contained in a container 4 of an evaporation apparatus 2, 2′, 2″. The evaporation apparatus 2, 2′, 2″ has a feed line through which a carrier gas may flow into the container 4. The carrier gas, for example hydrogen, nitrogen, or an inert gas, becomes saturated with the vapor of the starting material and exits the container 4 through a discharge line.

The feed line and discharge line of the container 4 are connected to a switching device 5, which has a number of valves that may be switched in such a way that a carrier gas flow supplied from an assembly of one or more inlet mass flow controllers 10, 11 (referred to in the following text as carrier gas mass flow controllers) flows either through the container 4 or past the container 4.

The assembly for providing a carrier gas mass flow consists in the exemplary embodiment of two mass flow controllers 10, 11, which have different flow ranges. The mass flow controller 11 may have a larger flow range than the mass flow controller 10, for example. The carrier gas feed line 6 is connected to both mass flow controllers 10, 11, wherein a shutoff valve is arranged in the feed line to the mass flow controller 11.

The source assembly is used to provide an organometallic starting material for a CVD reactor 1, 1′, 1″, in which one or more substrates 17 are supported on a heated susceptor 16, which forms the bottom of a process chamber 18.

The exemplary embodiments each have at least one CVD reactor 1, 1′, 1″. In the exemplary embodiment illustrated in FIG. 1, a process gas feed line 9, into which the vapor of the starting material transported by the carrier gas from the evaporation apparatus 2 is fed, opens into a gas inlet opening 15 of a CVD reactor 1.

In the exemplary embodiment shown in FIG. 2, three different process gas feed lines 9, 9′, 9″, into each of which a vapor of the starting material transported by the carrier gas from an evaporation apparatus 2, 2′, 2″ is fed, each open into a gas inlet opening 15 of a CVD reactor 1, 1′, 1″. Here, a single pressure regulator 8 with a discharge line split into a plurality of gas feed lines 12, 12′, 12″ is connected to a plurality of source assemblies of different CVD reactors 1, 1′, 1″.

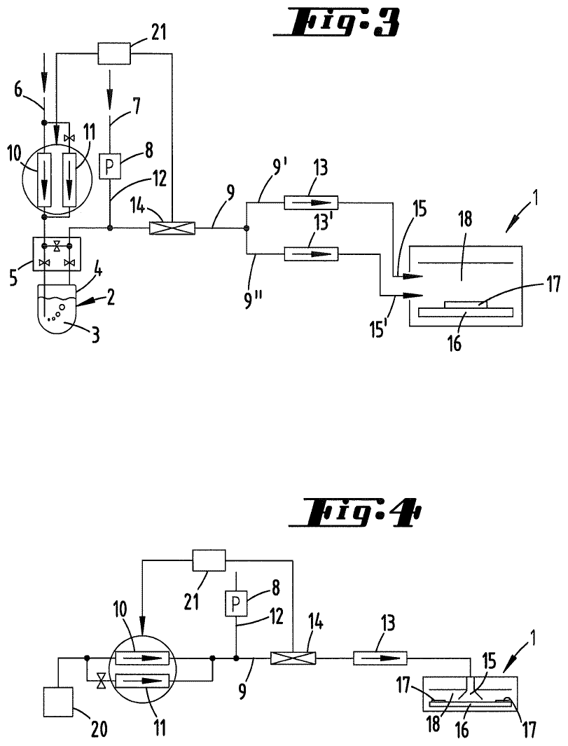

In the exemplary embodiment illustrated in FIG. 3, a process gas feed line 9, into which the vapor of the starting material transported by the carrier gas from the evaporation apparatus 2 is fed, splits into two process gas feed lines 9′, 9″. In each of these process gas feed lines 9′, 9″, there is a process gas mass flow controller 13, 13′. The mass flow regulated by the two process gas mass flow controllers 13, 13′ flows into two different gas inlet openings 15, 15′ of the same CVD reactor 1. Two individually regulated process gas flows are generated, which are fed at different points into a process chamber 18 of a CVD reactor.

The exemplary embodiments show a pressure regulator 8. The pressure regulator 8 is connected to a carrier gas feed line 7. Carrier gas feed line 7 may be connected to the same carrier gas source to which the carrier gas feed line 6 is also connected. However, it is also possible to connect the carrier gas feed line 7 to another carrier gas source. The carrier gas flow fed into the pressure regulator 8 flows through the pressure regulator 8, which is set up in such a way that the pressure in a gas feed line 12, 12′, 12″ connected to the outlet of the pressure regulator 8 is kept at a constant value. For this purpose, the pressure regulator 8 has a control loop. The pressure regulator 8 also keeps the total pressure in the containers 4 of the evaporation apparatuses 2, 2′, 2″ at a constant value. The gas feed lines 12, 12′, 12″ open into the process gas feed lines 9, 9′, 9″ downstream of the container 4.

The exemplary embodiments also show optional measuring apparatuses 14, 14′, 14″, with which the concentration or the partial pressure of the starting material in the carrier gas can be determined. In particular, an apparatus known by the name Epison may be used as a measuring apparatus. With this measuring apparatus, a measured value is obtained by a time-of-flight measurement, which depends on the one hand on the concentration and/or the partial pressure of the starting material, but on the other hand also on the total pressure in a measuring chamber of the measuring apparatus. The balancing gas flow generated by the pressure regulator 8 is fed into each process gas feed line 9, 9′, 9″ upstream of the measuring apparatus 14, 14′, 14″. In this way, the respective total pressures within each of the measuring chambers of the measuring apparatus 14, 14′, 14″ is maintained at a constant value.

In each of the process gas feed lines 9, 9′, 9″ there is a process gas mass flow controller 13, 13′, 13″, with which the mass flow of the process gas fed into the respective CVD reactor 1, 1′, 1″ through the process gas feed line 9, 9′, 9″ may be regulated. As a result of this configuration, the respective mass flow controllers 13, 13′, 13″ regulate the mass flow of a mixture consisting of a carrier gas and the vapor of a starting material, in which the partial pressure of the starting material is known. Any necessary adjustment of a setpoint of the process gas mass flow controller may be performed by using the value measured by the measuring apparatus 14, 14′, 14″.

In the exemplary embodiment illustrated in FIG. 4, the source 19 for providing a reactive gas conveyed in a carrier gas has a container 20, for example a gas bottle, in which a pure reactive gas, for example a hydride of an element of main group V or main group IV is stored. However, a different gas, for example propane, may also be stored in the gas cylinder. In particular, it may be provided that a diluted reactive gas is already stored in the container 20, for example a mixture of a reactive gas with a carrier gas, for example hydrogen or nitrogen. With a mass flow controller 10, which in the present case is s an inlet mass flow controller, a predetermined mass flow of the reactive gas or the gas mixture is provided. Parallel to the inlet mass flow controller 10 there is a mass flow controller 11 which has a larger range of values, and which may be optionally switched in.

A balancing gas flow is fed into the process gas flow with a pressure regulator 8 in such a way that the total pressure within the measuring apparatus 14 is kept at a constant value. The concentration of the process gas in the process gas feed line 9 may be determined in the measuring apparatus 14. The concentration of the reactive gas in the process gas flow through the process gas feed line 9 may be kept at a constant value with a control apparatus 21 via the inlet mass flow controller 10.

The container 20 may be formed by a central gas supply.

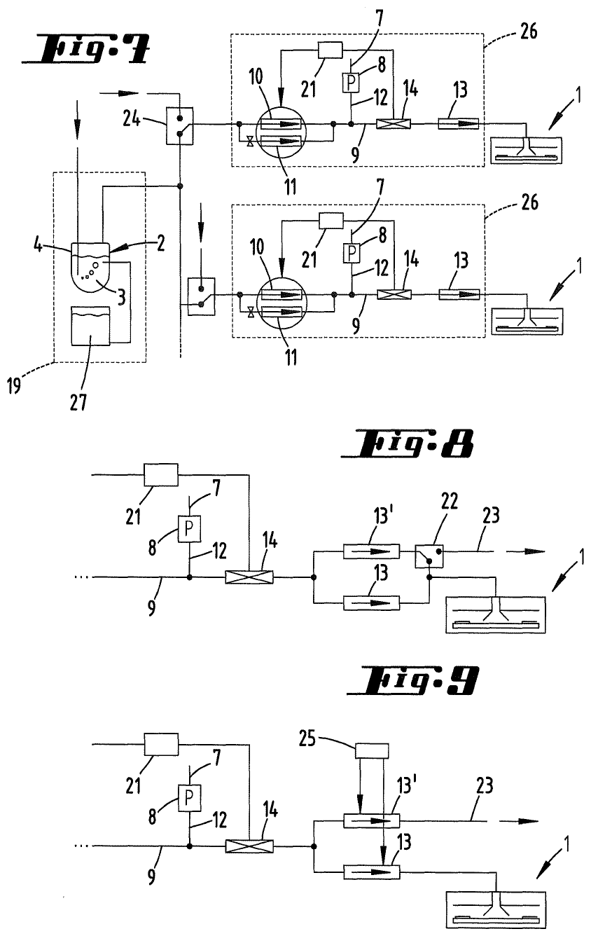

The source denoted with reference numeral 20 in FIG. 4 may also be formed by a source assembly as described in FIGS. 1 to 3, namely by an evaporation apparatus 2 with a container 4, in which a solid or liquid starting material 3 to be evaporated is located. Such an apparatus is shown in FIG. 7. A carrier gas is fed into the container 4 in the manner described above via at least one carrier gas mass flow controller 10, 11, so that a mixture of the vapor of the starting material and the carrier gas flows through the inlet mass flow controller 10, 11, wherein the concentration of the vapor of the starting material in the carrier gas may vary. The container 4 is part of a central evaporation source 19, which delivers a permanent vapor stream transported by a carrier gas, which is supplied to a plurality of local gas supply facilities 26. The content of the container 4 may be continuously refilled from another container 27.

FIG. 7 shows two local gas supply facilities 26 of such kind, each for supplying gas to a CVD reactor 1. Switching valves 24 are provided, with which the reactive starting material, which in this case is a mixture of a carrier gas and a vapor, may be fed into the inlet mass flow controller 10, 11. With the switching valve 24, a carrier gas or the reactive gas may be fed into the inlet mass flow controller 10 as desired. The carrier gas is fed in to flush the pipelines of the local gas supply facility 26. Each gas supply facility 26 has a closed loop control device 21 with which the mass flow of the reactive gas may be adjusted in such a way that the concentration of the starting material is maintained at a constant value at the measuring cell of the measuring apparatus 14.

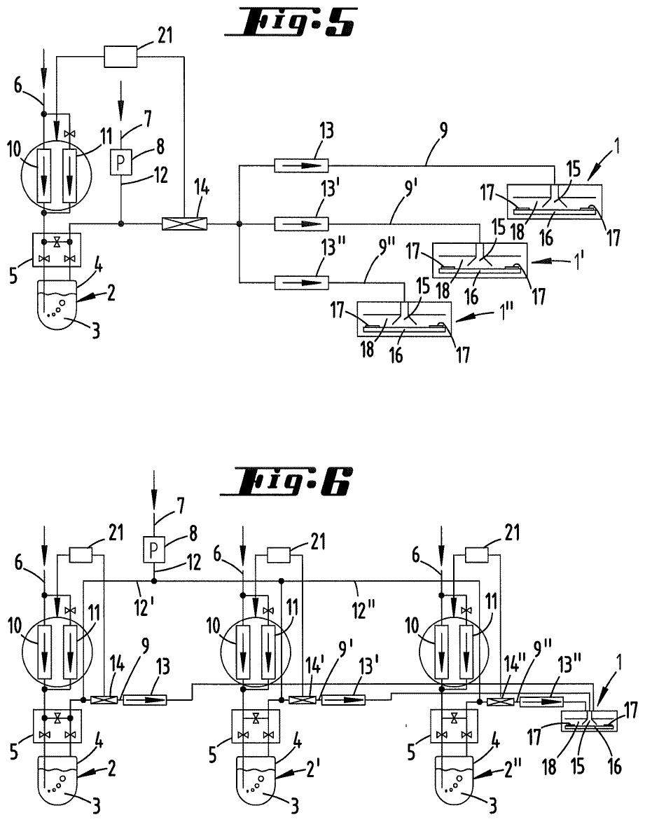

FIG. 5 shows a further exemplary embodiment as a variant of the embodiment shown in FIG. 3. Here, the mass flow of the process gas splits into several sub-flows, each of which is routed to different CVD reactors 1, 1′, 1″, wherein an individual process gas mass flow controller 13, 13′, 13″ is assigned to each process gas feed line 9, 9′, 9″ leading to a CVD reactor 1, 1′, 1″.

The exemplary embodiment illustrated in FIG. 6 shows a CVD reactor which is connected to several different sources of a solid or liquid starting material, for example an organometallic compound. A measuring apparatus 14, 14′, 14″ is assigned to each source, in order to measure the respective concentration of the starting material in the process gas feed line 9, 9′, 9″. The gas flow of the process gas flowing through each of the process gas feed lines 9, 9′, 9″ can be regulated with a process gas mass flow controller 13, 13′, 13″. The process gas mass flows flow into a gas inlet element of a CVD reactor, wherein the process gases can exit from various gas inlet openings of the gas inlet element.

FIG. 8 shows a further variant of the several exemplary embodiments explained above. A reactive gas or a mixture of a reactive gas with a carrier gas or a mixture of a vapor with a carrier gas is fed into the process gas feed line 9 in the manner described above, wherein a closed loop control device 21 may also be provided here, with which an inlet mass flow controller is actuated by specifying a setpoint for the mass flow controller 10, 11. A first process gas mass flow controller 13 is provided, which provides a mass flow of a process gas which is continuously fed into the CVD reactor 1. A process gas provided by a second process gas mass flow controller 13′ may optionally also be fed into the CVD reactor 1 or into a discharge gas line 23 with a switching valve 22. With an apparatus of such kind, the mass flow fed into the CVD reactor 1 may be changed in a very short time, because the total mass flow of the process gas flowing through the mass flow controller 13, 13′ remains constant. As a result, the effect of the control device 21 is not disturbed.

A similar apparatus is shown in FIG. 9. However, here the second process gas mass flow controller 13′ is connected directly to a discharge gas line 23, so that the mass flow flowing through the mass flow controller 13′ does not reach the CVD reactor 1, but only the mass flow through the first process gas mass flow controller 13. The mass flow of the process gas through the process gas mass flow controller 13 can be varied by means of an open loop control device 25. At the same time, the process gas mass flow into the discharge gas line 23 is also changed by the second process gas mass flow controller 13′. The two process gas mass flows are changed in such a way that the sum of the process gas mass flows flowing through the process gas mass flow controllers 13, 13′ remains constant. In this way, layers may be deposited on substrates in the CVD reactor 1, the layer properties of which change with the layer thickness. Because the overall flow of the process gas is kept constant in the exemplary embodiments illustrated in FIGS. 8 and 9, the closed loop control device 21 is not disturbed.

It is considered advantageous if the elements described above are arranged in the following order in the direction of flow of the carrier gas: The evaporation apparatus 2, 2′, 2″ is arranged upstream of the feed point of the gas feed line 12, 12′, 12″ of the pressure regulator 8. The measuring apparatus 14 is arranged downstream of the pressure regulator 8 and/or the feed point of the gas feed line 12, 12′, 12″ of the pressure regulator 8. The at least one process gas mass flow controller 13, 13′, 13″ is arranged downstream of the measuring apparatus 14.

It is further considered advantageous that several source assemblies, each having an evaporation apparatus 2, 2′, 2″ embodied as a bubbler, are connected in parallel, wherein a common pressure regulator 8 is used to keep a pressure in the container 4 of the bubbler constant. Various gas systems may be provided in order to feed process gases into different process chambers 18.

The preceding notes are intended to explain the inventions comprised in the application as a whole, each of which also independently develop the prior art at least through the following feature combinations, wherein two, several or all of said feature combinations may also be combined, namely:

An assembly which is characterized in that the gas stream flowing from the process gas feed line 9, 9′, 9″ into the CVD reactor is regulated with a process gas mass flow controller 13, 13′, 13″.

An assembly which is characterized in that the reactive gas conveyed through the process gas feed line 9, 9′, 9″ flows through the inlet mass flow controller 10, 11, and the gas source is a container that stores the reactive gas or is a vapor source 19 that provides a vapor conveyed in a carrier gas, or that a carrier gas flow provided by the inlet mass flow controller 10, 11 flows through an evaporation container 2 of an evaporation apparatus 2, 2′, 2″, and the vapor generated in the evaporation apparatus 2, 2′, 2″ is transported by the carrier gas in the process gas feed line 9, 9′, 9″.

An assembly which is characterized in that a measuring apparatus 14, 14′, 14″ is provided downstream of the pressure regulator 8 for measuring the concentration or the partial pressure of the vaporized or gas-phase starting material 3 in the process gas feed line 9, 9′, 9″.

An assembly which is characterized in that an outlet of the pressure regulator 8 with a plurality of gas feed lines 12, 12′, 12″, each of which is connected to a process gas feed line 9, 9′, 9″, each of which is assigned to a different CVD reactor 1, 1′, 1″.

An assembly which is characterized in that the process gas flow flowing through the process gas feed line 9 and kept at a predetermined total pressure by the pressure regulator 8 is divided into several partial flows, and/or that two process gas mass flow controllers 13, 13′ are connected in parallel, and/or that the process gas flow is fed into a process chamber 18 of the CVD reactor 1 through two different gas inlet openings 15, 15′, each being controlled according to the mass flow.

An assembly which is characterized in that the inlet mass flow controller 10, 11 is part of an inlet mass flow controller apparatus having a plurality of inlet mass flow controllers 10, 11, and/or that a switching device 5 is provided, with which the carrier gas flow may be fed optionally into the container 4 of the evaporation apparatus 2, 2′, 2″ or fed directly into the process gas feed line 9, 9′, 9″, and/or that the container 4 of the evaporation apparatus 2, 2′, 2″ may be heated or cooled.

An assembly which is characterized in that the output of the measuring apparatus 14, 14′, 14″ is connected to a plurality of parallel-connected process gas mass flow controllers 13, 13′, each of which is connected to a CVD reactor 1, 1′, 1″ via process gas feed lines 9, 9′, 9″.

An assembly characterized in that an output of the pressure regulator 8 with a plurality of gas feed lines 12, 12′, 12″ is connected by each to a different gas source 19; 2-5, with which various reactive gases are provided, which are connected to one or more CVD reactors 1, 1′, 1″ with process gas feed lines 9, 9′, 9″.

An assembly which is characterized by a closed loop control device 21 which specifies a setpoint value for the inlet mass flow controller 11 in order to maintain the concentration or the partial pressure of the starting material at a constant value in the process gas feed line 9, 9′, 9″.

A CVD reactor assembly which is characterized by an arrangement for providing a process gas that is fed into the CVD reactor 1, 1′, 1″.

A method for providing a process gas for use in a CVD reactor, wherein a mass flow of a reactive gas conveyed in a carrier gas is provided with an inlet mass flow controller 10, 11 and a gas source 19; 2-5, and is conveyed to one or more CVD reactors 1, 1′, 1″ through a process gas feed line 9, 9′, 9″.

A method which is characterized in that the concentration or the partial pressure of the starting material is measured with a measuring apparatus 14, 14′, 14″ in the process gas feed line 9, 9′, 9″, and in particular the setpoint of the process gas mass flow controller is corrected with a measured value obtained in this way, and/or the concentration or the partial pressure is kept at a constant value with the measured value obtained in this way by feeding a dilution gas into the process gas feed line (9, 9′, 9″) upstream of the measuring apparatus (14, 14′, 14″) with a mass flow controller (11).

A method which is characterized in that the mass flow of a carrier gas flowing from an outlet of the pressure regulator 8 is divided into a plurality of mass flows, each of which is discharged into process gas feed lines 9, 9′, 9″ which are different from each other and through which a process gas mass flow from an evaporation apparatus 2, 2′, 2″ to a CVD reactor 1, 1′, 1″.

A method characterized in that the process gas mass flow provided by the source 19; 2-5 is divided into several partial flows, each of which is controlled by a process gas mass flow controller 13, 13′ and flows through various gas inlet openings 15, 15′ into a process chamber 18 of the CVD reactor 1, 1′, 1″, or into different CVD reactors 1, 1′, 1″.

All features disclosed (by themselves, but also in combination with one another) are essential to the invention. The disclosure of the application herewith also includes the content of the disclosure of the associated/attached priority documents (copy of the previous application) in its entirety, also for the purpose of including features of said documents in claims of the present application. Even without the features of a referenced claim, the features of the subordinate claims characterize independent inventive developments of the prior art, in particular for the purpose of making divisional applications on the basis of said claims. The invention specified in each claim may additionally have one or more of the features defined in the preceding description, in particular those provided with reference numbers and/or indicated in the list of reference numbers. The invention further relates to design forms in which individual features named in the preceding description are not implemented, in particular if they are evidently unnecessary for the respective intended use or can be replaced by other technically equivalent means.

List of reference numerals

| | |
|---|---|
| 1 | CVD reactor |
| 1′ | CVD reactor |
| 1″ | CVD reactor |
| 2 | Evaporation apparatus |
| 2′ | Evaporation apparatus |
| 2″ | Evaporation apparatus |
| 3 | Starting material |
| 4 | Container |
| 5 | Switching device |
| 6 | Carrier gas feed line |
| 7 | Carrier gas feed line |
| 8 | Pressure regulator |
| 9 | Process gas feed line |
| 9′ | Process gas feed line |
| 9″ | Process gas feed line |
| 10 | Inlet mass flow |
| | controller |
| 11 | Inlet mass flow |
| | controller |
| 12 | Gas feed line |
| 12′ | Gas feed line |
| 12″ | Gas feed line |
| 13 | Process gas mass flow |
| | controller |
| 13′ | Process gas mass flow |
| | controller |
| 13″ | Process gas mass flow |
| | controller |
| 14 | Measuring apparatus |
| 14′ | Measuring apparatus |
| 14″ | Measuring apparatus |
| 15 | Gas inlet opening |
| 15′ | Gas inlet opening |
| 16 | Susceptor |
| 17 | Substrate |
| 18 | Process chamber |
| 19 | Central evaporation |
| | source |
| 20 | Container |
| 21 | Closed loop control |
| | device |
| 22 | Valve |
| 23 | Discharge gas line |
| 24 | Valve |
| 25 | Open-loop control |
| | device |
| 26 | local gas supply |
| | facilities |
| 27 | Container |

The invention claimed is:

1. An assembly for providing a process gas for use in a first chemical vapor deposition (CVD) reactor (1), the assembly comprising:
a first process gas feed line (9);
a carrier gas feed line (7);
a first gas source (2-5, 19, 20) for providing a mass flow of a starting material transported with a carrier gas, which is conveyed through the first process gas feed line (9) to the first CVD reactor (1), wherein the first gas source (2-5, 19, 20) has an inlet mass flow controller (10, 11);
a pressure regulator (8) for regulating a total pressure in the first process gas feed line (9), and feeding a balancing gas from the carrier gas feed line (7) into the first process gas feed line (9);
a measuring apparatus (14, 14′, 14″), arranged in the first process gas feed line (9), for measuring a concentration or a partial pressure of the starting material in the carrier gas;
a closed loop control device (21) for keeping the concentration or the partial pressure of the starting material at a first constant value in the first process gas feed line (9); and
a first process gas mass flow controller (13) is arranged downstream of the measuring apparatus (14, 14′, 14″),
wherein the closed loop control device (21) is configured to regulate the mass flow of the starting material flowing into the first CVD reactor (1) with the first process gas mass flow controller (13) while the total pressure is maintained at a second constant value by the pressure regulator (8),
wherein the measuring apparatus (14, 14′, 14″) is located in the first process gas feed line (9) between an outlet of the pressure regulator (8) and the process gas mass flow controller (13, 13′, 13″), and
wherein the starting material is in a gaseous phase.

2. The assembly of claim 1, wherein a reactive gas conveyed through the first process gas feed line (9) flows through the inlet mass flow controller (10, 11), and the first gas source is a vapor source (19) which includes a container storing the reactive gas.

3. The assembly of claim 1, further comprising:
a second process gas feed line (9′);
a first gas feed line (12′);
a second gas feed line (12″); and
a second CVD reactor (1′),
wherein an output of the pressure regulator (8) is connected to the first process gas feed line (9) through the first gas feed line (12′), and is connected to the second process gas feed line (9′) through the second gas feed line (12″), and
wherein the first process gas feed line (9) is fluidly connected to the first CVD reactor (1), and the second process gas feed line (9′) is fluidly connected to the second CVD reactor (1′).

4. The assembly of claim 1, wherein a flow of the process gas flowing through the first process gas feed line (9) and maintained by the pressure regulator (8) to have the total pressure equal to the second constant value, is divided into a plurality of sub-flows.

5. The assembly of claim 1, further comprising a second process gas mass flow controller (13′) connected in parallel to the first process gas mass flow controller (13), wherein either:
(i) the first process gas mass flow controller (13) is configured to control a first mass flow of the process gas that flows into a process chamber (18) of the first CVD reactor (1) through a first gas inlet opening (15) of the first CVD reactor (1), and the second process gas mass flow controller (13) is configured to control a second mass flow of the process gas that flows into the process chamber (18) of the first CVD through a second gas inlet opening (15′) of the first CVD reactor (1), or
(ii) the first process gas mass flow controller (13) is configured to control a third mass flow of the process gas that flows into the process chamber (18) of the first CVD reactor (1), and the second process gas mass flow controller (13′) is configured to control a fourth mass flow of the process gas that flows into a process chamber (18) of a second CVD reactor (1′).

6. The assembly of claim 1, further comprising:
a second process gas feed line (9′);
a first gas feed line (12′);
a second gas feed line (12″);
a second CVD reactor (1′); and
a second gas source (19; 2-5),
wherein an output of the pressure regulator (8) is connected by the first gas feed line (12′) to the first gas source (19; 2-5), and is connected by the second gas feed line (12″) to the second gas source (19; 2-5), various reactive gases being provided by the first and second gas sources (19; 2-5),
wherein the first gas source (19; 2-5) is connected to the first CVD reactor (1) by the first process gas feed line (9), and
wherein the second gas source (19; 2-5) is connected to the second CVD reactor (1′) by the second process gas feed line (9′).

7. The assembly of claim 1, wherein the closed loop control device (21) specifies a setpoint for the inlet mass flow controller (11) in order to maintain the concentration or the partial pressure of the starting material at the first constant value in the first process gas feed line (9).

8. A chemical vapor deposition (CVD) reactor assembly, comprising:
at least one carrier gas source; and
the assembly of claim 1 for providing the process gas for use in the first CVD reactor (1); and
the first CVD reactor (1).

9. A method for providing a process gas, comprising:
regulating, with a pressure regulator (8), a total pressure in a first process gas feed line (9);
measuring, with a measuring apparatus (14, 14′, 14″), a concentration or a partial pressure of a starting material in the first process gas feed line (9);
maintaining, with a first process gas mass flow controller (13) arranged downstream of the measuring apparatus (14, 14′, 14″), a mass flow of the starting material flowing into a first CVD reactor (1) at a first constant value;
feeding, by the pressure regulator (8), a balancing gas into the first process gas feed line (9) so as to maintain the total pressure in the first process gas feed line (9) at a second constant value,
wherein the measuring apparatus (14, 14′, 14″) is located in the first process gas feed line (9) between an outlet of the pressure regulator (8) and the first process gas mass flow controller (13).

10. The method of claim 9, further comprising at least one of:
correcting a setpoint of the first process gas mass flow controller (13) with the measurement of the concentration or the partial pressure of the starting material provided by the measuring apparatus (14, 14′, 14″), or
maintaining the concentration or the partial pressure of the starting material in the first process gas feed line (9) at a third constant value with the measurement of the concentration or the partial pressure of the starting material provided by the measuring apparatus (14, 14′, 14″).

11. The method of claim 9, wherein a mass flow of a carrier gas flowing out of an outlet of the pressure regulator (8) discharges into the first process gas feed line (9) and a second process gas feed line (9′), through each of which a process gas mass flow flows from an evaporation apparatus (2, 2′, 2″) to the first CVD reactor (1).

12. The method of claim 9, wherein a process gas mass flow provided by a source (19; 2-5) is divided into a first and second partial flow, and wherein either:
(i) the first process gas mass flow controller (13) controls a flow of the first partial flow into a process chamber (18) of the first CVD reactor (1) and a second process gas mass flow controller (13′) controls a flow of the second partial flow into the process chamber (18) of the first CVD reactor (1), or
(ii) the first process gas mass flow controller (13) controls the flow of the first partial flow into the process chamber (18) of the first CVD reactor (1) and the second process gas mass flow controller (13′) controls the flow of the second partial flow into a process chamber (18) of a second CVD reactor (1′).

13. (canceled)

14. The assembly of claim 1, further comprising a vapor source (19) for providing a vapor that is transported in the carrier gas.

15. The assembly of claim 1, wherein the carrier gas is provided by the inlet mass flow controller (10, 11) and flows through an evaporation container (2) of an evaporation apparatus (2, 2′, 2″), and a vapor generated in the evaporation apparatus (2, 2′, 2″) is transported in the first process gas feed line (9) by the carrier gas.
